(19) United States
(12) Patent Application Publication
(10) Pub. No.: US 2009/0086521 A1
(43) Pub. Date: Apr. 2, 2009

(54) MULTIPLE ANTIFUSE MEMORY CELLS AND METHODS TO FORM, PROGRAM, AND SENSE THE SAME

(76) Inventors: S. Brad Herner, San Jose, CA (US); Roy E. Scheuerlein, Cupertino, CA (US); Christopher J. Petti, Mountain View, CA (US)

Correspondence Address: DUGAN & DUGAN, PC, 245 Saw Mill River Road, Suite 309, Hawthorne, NY, 10532, US

(21) Appl. No.: 11/864,870

(22) Filed: Sep. 28, 2007

(51) Int. Cl. G11C 5/06; G11C 17/06; H01L 21/44; H01L 29/00; G11C 17/18

(52) U.S. Cl. 365/63; 257/530; 365/225.7; 365/96; 438/600; 257/E29.001; 257/E21.476

(57) ABSTRACT

Methods are described to fabricate, program, and sense a multilevel one-time-programmable memory cell including a steering element such as a diode and two, three, or more dielectric antifuses in series. The antifuses may be of different thicknesses, or may be formed of dielectric materials having different dielectric constants, or both. The antifuses and programming pulses are selected such that when the cell is programmed, the largest voltage drop in the memory cell is across only one of the antifuses, while the other antifuses allow some leakage current. In some embodiments, the antifuse with the largest voltage drop breaks down, while the other antifuses remain intact. In this way, the antifuses can be broken down individually, so a memory cell having two, three, or more antifuses may achieve any of three, four, or more unique data states.

### RELATED APPLICATIONS

This application is related to Herner, U.S. patent application Ser. No. ______, (Atty. Docket No. [MXD-0343]), “VERTICAL DIODE BASED MEMORY CELLS HAVING A LOWERED PROGRAMMING VOLTAGE AND METHODS OF FORMING THE SAME” filed on even date herewith and hereby incorporated by reference in its entirety.

### BACKGROUND OF THE INVENTION

It is known to form a nonvolatile memory cell having a diode and an antifuse in series, as in Johnson et al., U.S. Pat. No. 6,034,882, “Vertically Stacked Field Programmable Nonvolatile Memory and Method of Fabrication”; and in Herner et al., U.S. Pat. No. 6,952,030, “High-density three-dimensional memory cell.” If the diode is vertically oriented, and multiple memory levels of such devices are stacked above a wafer substrate, a highly dense memory array can be formed.

In Cleeves, US Patent Publication No. 20070002603, “Memory Cell with High-K Antifuse for Reverse Bias Programming,” a single antifuse is ruptured with reverse bias and trimmed with forward bias to define multiple states. Such reverse bias is difficult to apply through a diode in the cell. Such multiple-state memory cells are also difficult to manufacture and program with high yield and reliability.

For adequate manufacturability a nonvolatile memory cell including a diode and an antifuse can be in one of two data states, where the antifuse layer is either intact or broken down. It would be advantageous to increase device density further by devising a diode-antifuse memory cell that can attain more than two data states and does not require reverse bias to program the cells.

### SUMMARY OF THE PREFERRED EMBODIMENTS

The present invention is defined by the following claims, and nothing in this section should be taken as a limitation on those claims. In general, the invention is directed to multiple antifuse memory cells and methods to form, program, and sense such memory cells.

In a first aspect of the invention, a method is provided for programming a memory cell. The memory cell includes a steering element; a first dielectric antifuse layer; and a second dielectric antifuse layer. The steering element, first dielectric antifuse layer, and second dielectric antifuse layer are all arranged in series between a first conductor and a second conductor. The method includes applying a first programming pulse between the first conductor and the second conductor, wherein the first programming pulse results in dielectric breakdown of the first dielectric antifuse layer.

In a second aspect of the invention, a method is provided to program memory cells in a memory array. Each memory cell includes a diode, a first dielectric antifuse layer, and a second dielectric antifuse layer. The diode, the first dielectric antifuse layer, and the second dielectric antifuse layer of each memory cell are arranged in series between a first conductor and a second conductor of the memory cell. The method includes (1) applying a first programming pulse between the first conductor and second conductor of a first plurality of the memory cells in a first memory cell state, wherein, after application of the first programming pulse, the first plurality of memory cells changes to a second memory cell state; and (2) applying a second programming pulse between the first conductor and second conductor of a second plurality of the memory cells, wherein, after application of the second programming pulse, the second plurality of memory cells changes to a third memory cell state.

In a third aspect of the invention, a method is provided for programming memory cells in a memory array. A first memory cell, a second memory cell, and a third memory cell of the memory cells each include a diode, a first dielectric antifuse layer, and a second dielectric antifuse layer. The diode, first dielectric antifuse layer, and second dielectric antifuse layer of each memory cell are arranged in series between a first conductor and a second conductor of the memory cell. The method includes (1) applying a first programming pulse between the first conductor and the second conductor of the second memory cell; and (2) applying a second programming pulse between the first conductor and the second conductor of the third memory cell. After application of the first and second programming pulses, the first memory cell is in a first data state, the second memory cell is in a second data state, and the third memory cell is in a third data state. The first data state is not the same as the second data state, and the third data state is not the same as the first data state or the second data state.

In a fourth aspect of the invention, a method is provided to form a nonvolatile memory cell. The method includes (1) forming a rail-shaped bottom conductor above a substrate; (2) forming a rail-shaped top conductor above the bottom conductor; (3) forming a vertically oriented diode; (4) forming a first dielectric antifuse layer; and (5) forming a second dielectric antifuse layer. The diode, the first dielectric antifuse layer, and the second dielectric antifuse layer are electrically in series and disposed between the bottom conductor and the top conductor.

In a fifth aspect of the invention, a method is provided for reading a memory cell of a nonvolatile memory array, the memory cell having at least two antifuse layers in series with a diode and a conductive layer between the antifuse layers. The memory cell is in one of at least three resistance states. The method includes (1) impressing a read voltage across the memory cell so as to generate a read current through the memory cell, and (2) based on the read current, detecting in which of the at least three resistance states the memory cell resides.

In a sixth aspect of the invention, a method is provided to program memory cells in a memory array. Each memory cell includes a diode, a first dielectric antifuse layer, and a second dielectric antifuse layer. The diode, the first dielectric antifuse layer, and the second dielectric antifuse layer of each memory cell are arranged in series between a first conductor and a second conductor of the memory cell. The method includes (1) determining a desired memory state for a first memory cell of the memory array; and (2) if the desired memory state for the first memory cell is a first memory state, applying a first programming pulse between the first conductor and second conductor of the first memory cell. After application of the first programming pulse, the first dielectric antifuse layer of the first memory cell is broken down, but the second dielectric antifuse layer of the first memory cell is not broken down.

In a seventh aspect of the invention, a first memory level of an integrated circuit monolithically formed above a substrate is provided. The first memory level includes (1) a plurality of substantially parallel, substantially coplanar bottom conductors; (2) a plurality of substantially parallel, substantially coplanar top conductors above the bottom conductors; (3) a plurality of vertically oriented diodes; (4) a plurality of first dielectric antifuse layers; (5) a plurality of second dielectric antifuse layers; and (6) a plurality of memory cells, wherein each memory cell comprises one of the diodes, one of the first dielectric antifuse layers, and one of the second dielectric antifuse layers disposed and arranged electrically in series between one of the bottom conductors and one of the top conductors.

In an eighth aspect of the invention, a monolithic three dimensional memory array is provided that includes a first memory level monolithically formed above a substrate, the first memory level having (1) a plurality of substantially parallel, substantially coplanar bottom conductors; (2) a plurality of substantially parallel, substantially coplanar top conductors above the bottom conductors; (3) a plurality of vertically oriented diodes; (4) a plurality of first dielectric antifuse layers; (5) a plurality of second dielectric antifuse layers; and (6) a plurality of memory cells. Each memory cell comprises one of the diodes, one of the first dielectric antifuse layers, and one of the second dielectric antifuse layers disposed between and arranged electrically in series between one of the bottom conductors and one of the top conductors. The first dielectric antifuse layer of each memory cell is not in contact with the second dielectric antifuse layer. The monolithic three dimensional memory array also includes a second memory level monolithically formed above the first memory level.

In a ninth aspect to the invention, a nonvolatile memory cell is provided that includes (1) a bottom conductor; (2) a top conductor above the bottom conductor; (3) a vertically oriented diode; (4) a first dielectric antifuse layer; and (5) a second dielectric antifuse layer. The diode, the first dielectric antifuse layer, and the second dielectric antifuse layer are disposed and arranged electrically in series between the bottom conductor and the top conductor. Numerous other aspects are provided.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a perspective view of a memory level according to an embodiment of U.S. patent application Ser. No. 11/560,283.

FIG. 2 is a perspective view of an embodiment of the present invention.

FIG. 4 is a perspective view of an alternative embodiment of the present invention.

FIG. 5 is a perspective view of an alternative embodiment of the present invention.

FIG. 6 is a perspective view of an alternative embodiment of the present invention.

FIG. 7 is an I-V curve showing dielectric breakdown of a first dielectric antifuse of the present invention with current limiting.

FIG. 8 is a graph showing breakdown field vs. thickness for a typical dielectric.

FIG. 9 is a series of I-V curves for different data states of a memory cell according to an embodiment of the present invention, where read is done at a single read voltage V_{R}.

FIG. 10 is a series of I-V curves for different data states of a memory cell according to an embodiment of the present invention, where a two-step read is performed.

FIGS. 11a-11d are cross-sectional views showing stages in formation of two memory levels according to an embodiment of the present invention.

FIG. 12 is a cross-sectional view of an alternative embodiment of the present invention.

FIGS. 13a-13c are views of an alternative embodiment of the present invention. FIGS. 13a and 13c are cross-sectional views, while FIG. 13b is a plan view.

### DETAILED DESCRIPTION OF THE PREFERRED EMBODIMENTS

A known type of nonvolatile memory cell includes a diode and an antifuse in series. One type of antifuse is a dielectric antifuse. A dielectric antifuse is formed of dielectric material, and is fabricated in an initial, high-resistance state. When a read voltage is applied across the antifuse, little or no current flows across it. When a substantially larger programming voltage is applied across the antifuse, however, the dielectric material of the antifuse breaks down. A low-resistance rupture region forms through the dielectric antifuse, and, after breakdown of the antifuse, substantially more current flows with the same read voltage applied. This difference in current between a cell including an intact antifuse and one in which the antifuse has broken down can correspond to the data state of the memory cell.

A diode is a non-ohmic device which can be used to provide electrical isolation between cells. When a diode is included in series with the antifuse, one memory cell can be programmed without unintentionally programming cells sharing the same bit line or word line. A highly dense cross-point memory array is formed by arranging a vertically oriented diode and an antifuse in series, each at the intersection of a top and bottom conductor. Such a memory level is shown in FIG. 1, which includes bottom conductors 200, top conductors 400, with diodes 302 and antifuses 118 disposed between them. Two, three, four, or more such memory levels can be stacked above one another, all formed above a semiconductor substrate. A monolithic three dimensional memory array of this type is described in Herner, U.S. patent application Ser. No. 11/560,283, “Method for Making a P-I-N Diode Crystallized Adjacent to a Silicide in Series with A Dielectric Antifuse,” filed Nov. 15, 2006, hereinafter the '283 application, owned by the assignee of the present invention and hereby incorporated by reference.

Device density in semiconductor devices is increased by making dimensions smaller, by vertically stacking devices, and, for memory, by increasing the number of data states each memory cell can achieve. Multilevel cells in a two-terminal device with resistivity-switching materials, such as binary metal oxides, have been described, as in Herner et al., US Patent Publication No. 20060250837, “Nonvolatile Memory Cell Comprising a Diode and a Resistance-Switching Material,” filed Mar. 31, 2006, hereinafter the '837 publication; or polycrystalline silicon (or polysilicon), as in Kumar et al., U.S. patent application Ser. No. 11/496,986, “Method For Using A Memory Cell Comprising Switchable Semiconductor Memory Element With Trimmable Resistance,” filed Jul. 31, 2006, hereinafter the '986 application, both owned by the assignee of the present invention and both hereby incorporated by reference.

If more than one antifuse were arranged in series with a diode, density could be increased by rupturing the antifuses serially, where breakdown of each antifuse defines a distinct data state. It has been considered impractical, however, to reliably break down one antifuse without breaking down others in series which are subjected to the same electrical programming pulse.

In the present invention, it has been found that by carefully selecting and controlling thickness, quality, and/or materials of the antifuses, and by limiting current during antifuse programming, a memory cell can be formed having multiple antifuses in which the conductivity of the cell has more than two stable values that can be sensed as more than two data states. It is believed that this indicates that the antifuses are broken down individually and sequentially. It is also possible that there are other explanations.

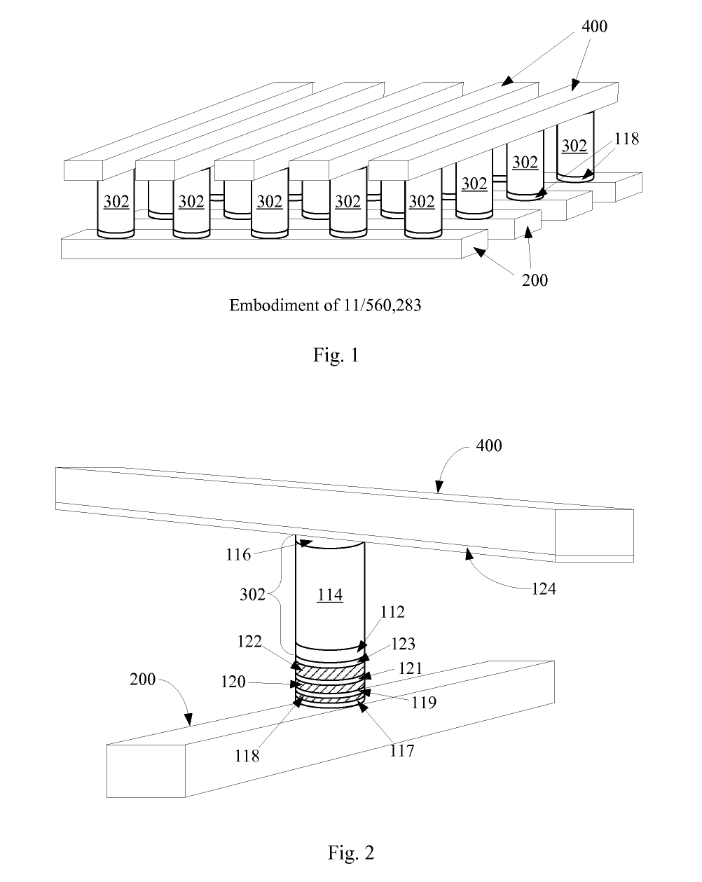

An embodiment of the present invention is shown in FIG. 2. The cell is disposed between bottom conductor 200 and top conductor 400, which preferably extend perpendicular to each other. Between the conductors are first conductive layer 117, thinnest dielectric antifuse layer 118, second conductive layer 119, middle dielectric antifuse layer 120, third conductive layer 121, thickest dielectric antifuse layer 122, and fourth conductive layer 123. Fewer or more antifuse layers and/or conductive layers may be used (e.g., 2, 3, 4, 5, 6, 7, etc.). In series with the dielectric antifuses and conductive layers is a vertically oriented p-i-n diode 302; in this example diode 302 is a polysilicon diode comprising bottom heavily doped p-type layer 112, middle intrinsic layer 114, and top heavily doped n-type layer 116. (In some embodiments, the position of the n-type and p-type layers may be reversed.)

When the first dielectric antifuse layer breaks down, a conductive rupture region is formed through it, concentrating current. If another dielectric antifuse is immediately adjacent, with no intervening conductive layer, during programming the rupture is likely to continue through the next dielectric antifuse layer. It is preferred, then for adjacent antifuse layers, like layer 118 and layer 120, or layer 120 and layer 122, not to be in contact with each other. Intervening conductive layers like layer 119 and 121 tend to diffuse the current between a broken down layer and an intact layer. Further, placing the dielectric antifuse layer between conductive layers in such a metal-insulator-metal structure may make breakdown more uniform and controllable. It's preferred, then, to sandwich every dielectric antifuse layer between conductive layers. The breakdown voltage of dielectrics has a non-linear dependence on thickness, so two separate thicknesses of dielectric separated by a conductive layer have different breakdown characteristics than the sum of the two dielectric thicknesses without a layer between them. These conductive layers will typically all be of the same material, for example titanium nitride, tantalum nitride, etc., and of the same thickness, for example between about 20 and about 100 angstroms, for example about 50 angstroms. It will be understood that differing conductivity material types and/or thicknesses may be used.

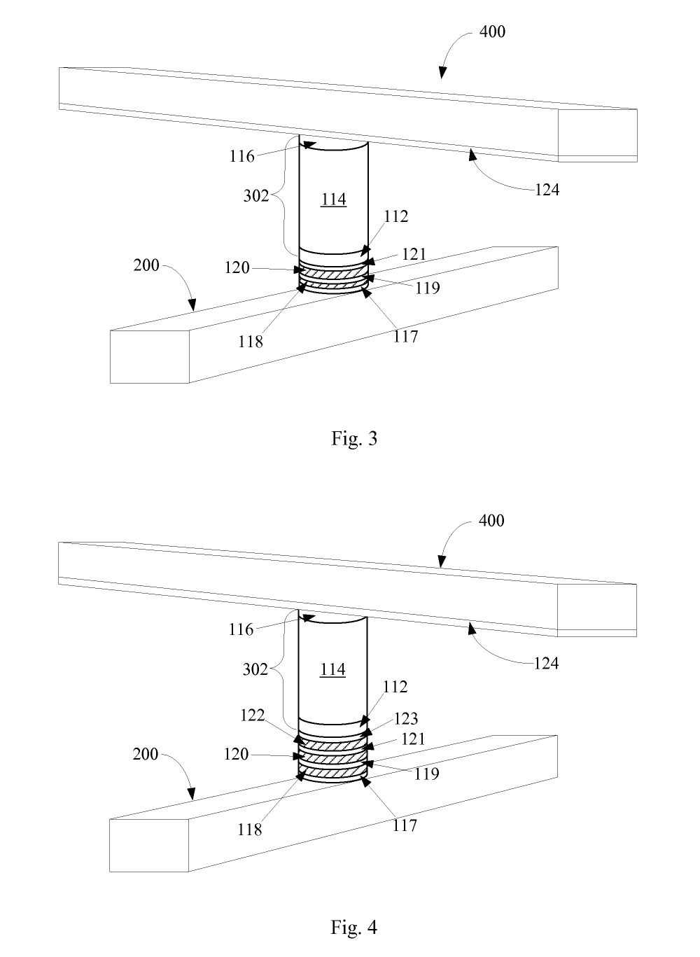

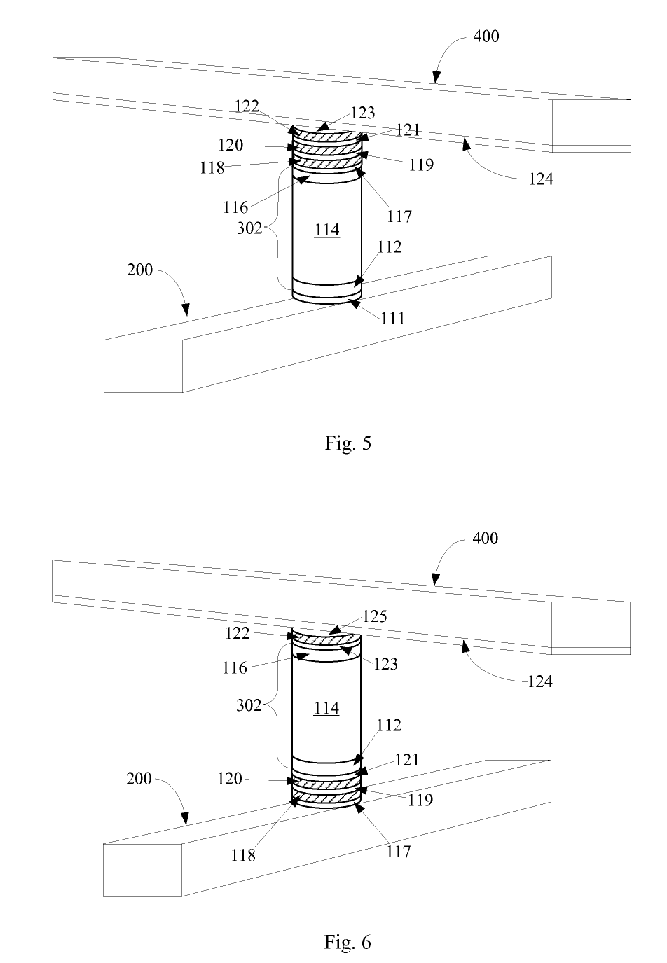

A memory cell formed according to aspects of the present invention includes two or more dielectric antifuse layers arranged in series. There may be three dielectric antifuse layers, as shown in the example in FIG. 2, two antifuses, four antifuses, or more. An embodiment shown in FIG. 3 has two antifuses. Thinner dielectric antifuse layer 118 may be, for example, 15 angstroms of HfO₂, and is formed on bottom conductive layer 117. Conductive layer 119 separates antifuse layer 118 from second antifuse layer 120, which may be, for example, 30 angstroms of HfO₂. Other antifuse layer thicknesses may be employed. In the embodiment of FIG. 3, conductive layer 121 separates dielectric antifuse 120 from diode 302 above. In these various embodiments, the dielectric antifuses themselves are chosen to have different breakdown characteristics and, in some embodiments, break down individually and sequentially. For selective breakdown to be achieved, the individual antifuses must break down under different conditions. In some embodiments, the dielectric antifuse layers are of the same material, but different thicknesses, as in the example shown in FIG. 2. In other embodiments, the dielectric antifuse layers may be of different dielectric materials, and of either the same thickness, as in FIG. 4, or of different thicknesses. In FIG. 2, all three dielectric antifuses are below the diode. In alternative embodiments, as in FIG. 5, the antifuses may be above diode 302, disposed between diode 302 and top conductor 400 (in this embodiment conductive barrier layer 111 is disposed between bottom conductor 200 and diode 302.) Alternatively, as in FIG. 6, one or more dielectric antifuse layers may be above diode 302, disposed between diode 302 and top conductor 400, while one or more dielectric antifuse layers are below diode 302, disposed between diode 302 and bottom conductor 200. In the embodiment shown, dielectric antifuse 122 is between conductive layers 123 and 125.

As described in Hemer et al., US Patent Publication No. 20050226067, “Nonvolatile Memory Cell Operating by Increasing Order in Polycrystalline Semiconductor Material,” filed Jun. 8, 2005, hereinafter the '067 publication; in Hemer et al., U.S. Pat. No. 7,176,064, “Memory Cell Comprising a Semiconductor Junction Diode Crystallized Adjacent to a Silicide,” hereinafter the '064 patent, both owned by the assignee of the present invention and both hereby incorporated by reference, and in the '283 application, earlier incorporated, when semiconductor material such as silicon, germanium, or silicon-germanium is deposited amorphous and is crystallized in contact only with materials with which it has a high lattice mismatch, such as titanium nitride and silicon dioxide, the resulting polysilicon (or polygermanium, or polysilicon-polygermanium) forms with a high number of crystalline defects, causing it to be high-resistivity. Application of a programming pulse through this high-defect polysilicon apparently alters the polysilicon, causing it to become lower-resistivity.

It has been found, however, that when deposited amorphous silicon is crystallized in contact with a layer of an appropriate silicide, for example titanium silicide or cobalt silicide, the resulting crystallized silicon is much higher quality, with fewer defects, and has much lower resistivity. The lattice spacing of titanium silicide or cobalt silicide is very close to that of silicon, and it is believed that when amorphous silicon is crystallized in contact with a layer of an appropriate silicide at a favorable orientation, the silicide provides a template for crystal growth of silicon, minimizing formation of defects. Unlike the high-defect silicon crystallized adjacent only to materials with which it has a high lattice mismatch, application of a large electrical pulse does not appreciably change the resistivity of this low-defect, low-resistivity silicon crystallized in contact with the silicide layer.

It is advantageous in embodiments of the present invention to use a diode formed of such low-resistivity polycrystalline semiconductor material. Because the semiconductor material of the diode is in a low-resistivity state as formed, it need not be converted to a lower resistivity state. Lower programming voltages can thus be used, which is generally advantageous. Referring to the embodiment of FIG. 2, a silicide layer in contact with diode 302 can be formed by depositing the semiconductor material of the diode in an amorphous state, and forming bottom layer 124 of top conductor 400 of an appropriate silicide-forming metal such as titanium or cobalt. When the completed structure is annealed, the titanium or cobalt of layer 124 reacts with the silicon at the top of diode 302, forming a silicide layer (not shown). When the temperature at which crystallization begins is reached, the silicide layer acts as a template, so the semiconductor material of diode 302 crystallizes with few defects.

### Programming and Sensing

To cause breakdown of the first dielectric antifuse layer while leaving the other one, two, or more dielectric antifuse layers intact, programming conditions must be carefully controlled.

In one embodiment, the memory cell includes three dielectric antifuse layers, all formed of the same material. The antifuse material is an appropriate dielectric material, such as SiO₂, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend or blends thereof. Referring to FIG. 2, to assure good quality and uniformity, dielectric antifuse layers 118, 120, and 122 may be deposited by atomic layer deposition (ALD). In the embodiment of FIG. 2, dielectric antifuse layer 118 is thinnest, dielectric antifuse layer 120 is thicker, and dielectric antifuse layer 122 is thicker still. In one embodiment, suppose all three layers are HfO₂, and may have thicknesses of, for example, about 20, about 30 and about 40 angstroms, respectively, which may be separated from each other, and from bottom conductor 200 below and diode 302 above, by conductive layers 117, 119, 121, and 123, all of which may be, for example, about 50 angstroms of titanium nitride. Clearly, this is only one example; many other arrangements are possible.

A property of thin films of dielectrics is the electric breakdown field E_{BV} at which the dielectric will rupture, or break down. This breakdown field E_{BV} depends on the thickness of the dielectric. Referring to FIG. 8, which shows E_{BV} vs. thickness for a typical dielectric, it will be seen that at thinner film thickness, E_{BV} is higher. Differences in E_{BV} can be used to form antifuse layers with different breakdown voltages. Other properties of dielectrics can affect the breakdown voltage of antifuse layers. For example, the dielectric constant or even the method of depositing or growing the dielectric antifuse layer can affect its breakdown voltage. These and any other methods of producing antifuse layers with different breakdown characteristics are comprehended as possible embodiments of the present invention.

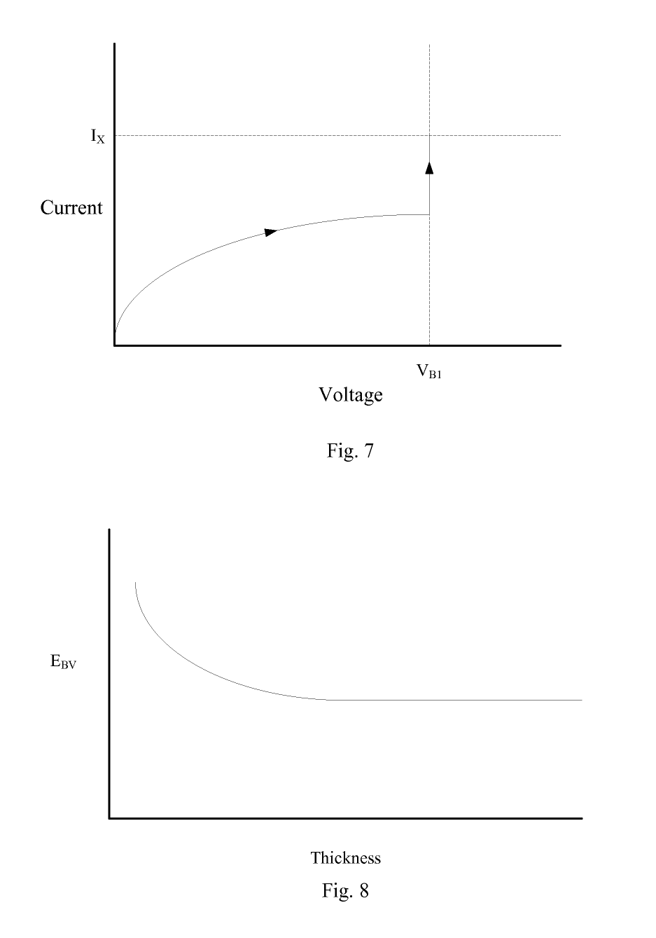

FIG. 7 is an I-V curve showing breakdown of first dielectric antifuse layer 122 of FIG. 2. As voltage increases, current increases only gradually until dielectric antifuse layer 122 breaks down at voltage V_{B1}. When breakdown takes place, a conductive rupture region forms through dielectric antifuse layer 122, and the current flowing through it, and through the memory cell, abruptly increases, and the entire applied voltage will then be dropped across the remaining antifuses. This may cause one or more of them to rupture. Thus, as shown on FIG. 7, there typically will be external circuitry which provides a limit I_{X} to the current after the initial breakdown. In this way, the voltage across the cell is reduced after the initial breakdown, so that the lower limited current level is maintained, and thus the remaining antifuses 120 and 118 remain intact. With careful selection of applied voltages and current limits, one, two, or all three antifuses can be ruptured.

For the embodiment of FIG. 2, suppose this memory cell includes a thickest antifuse 122, an antifuse of intermediate thickness 120, and a thin antifuse 118. The details of programming operation for this cell are as follows: A first programming pulse is applied between top conductor 400 and bottom conductor 200. The voltage of the pulse V₁ is selected such that the resulting electric field across the antifuses is greater than the breakdown field of thickest antifuse 122, but less than the breakdown field of the intermediate antifuse 120. The voltage of the programming pulse is the sum of the turn-on voltage for diode 302, which, as noted, is low-resistivity, and the voltages across each of the three antifuse layers 118, 120 and 122. This voltage may be between 4 and 10 volts, preferably less than about 7 volts, for example, about 6.5 volts. A current limit is applied that, while allowing the breakdown of thickest antifuse 122, after this breakdown, the voltage across the cell drops to a level that is safe for the remaining antifuses 120 and 118. This current limit may be between 1 and 10 microamps, for example, about 3 microamps. Other current limits may be employed.

After breakdown of thick dielectric antifuse layer 122, in order to break down intermediate dielectric antifuse layer 120, a second programming pulse having a voltage V₂, which in some embodiments is lower than the voltage V₁ of the first programming pulse, for example about 6 volts, is applied between top conductor 400 and bottom conductor 200. Again, if the applied voltage is such that the electric field across the two antifuses is higher than the breakdown field of the intermediate antifuse 120, but lower than the breakdown field of the thinner antifuse 118, then intermediate antifuse 120 will rupture while the thinner antifuse 118 remains intact.

As during the breakdown of thick dielectric antifuse layer 122, current is limited. Current through the memory cell increases abruptly when intermediate dielectric antifuse layer 120 breaks down, but only to the limit; in this way breakdown of thin dielectric antifuse layer 118 is prevented. In one example, current may be limited to about 15 microamps, although other current limits may be employed.

To break down the final thin dielectric antifuse layer 118, a third programming pulse having a voltage V₃, which in some embodiments can be less than either V₂ or V₁, for example about 5.5 volts, is applied between top conductor 400 and bottom conductor 200. Both dielectric antifuse layers 122 and 120 allow significant current flow through the conductive rupture regions formed during breakdown. The largest voltage drop, then, is across thin dielectric antifuse layer 118, which causes it to break down. As there is no remaining antifuse to protect, it is not essential to limit current during programming of the final dielectric antifuse layer, though a skilled practitioner may choose to do so for other reasons. In one embodiment current may be limited to about 150 microamps or some other suitable level.

In the example just provided, when three antifuses were to be broken down, breakdown was done sequentially. The first antifuse was broken down, leaving the remaining two intact; then the second antifuse was broken down, leaving the third intact; and finally the third antifuse was broken down. In alternative embodiments, however, in an array of multi-level one-time programmable cells, it may be preferred, when the desired data state for a memory cell is for all antifuses to be broken down, to break down all antifuses in a single step, with a single higher-amplitude pulse. This scheme offers the advantage of faster writing per cell. This pulse has higher voltage, however, which has other disadvantages, including reduced bandwidth. In the same memory array, in another cell, which is to have only one dielectric antifuse broken down while the others remain intact, the thickest dielectric antifuse is broken down by a lower-amplitude programming pulse, leaving the other dielectric antifuses intact, as described. In an alternative embodiment the first programming pulse is selected to cause the cell to break down two of the antifuse layers and leave the third intact. These programming pulses can also be used in combination to program an array of memory cells to various memory states. The appropriate pulse can be chosen for individual cells depending on the desired final state. In this way, any of the four read states may be obtained with a maximum of one programming pulse.

In alternative embodiments, an array of memory cells like those described herein, having two or more dielectric antifuses in series with a steering element, the dielectric antifuses separated by conductive layers, may be used as an array of two-state memory cells, in which no antifuses are broken down in unprogrammed cell, while all antifuses are broken down in programmed cells.

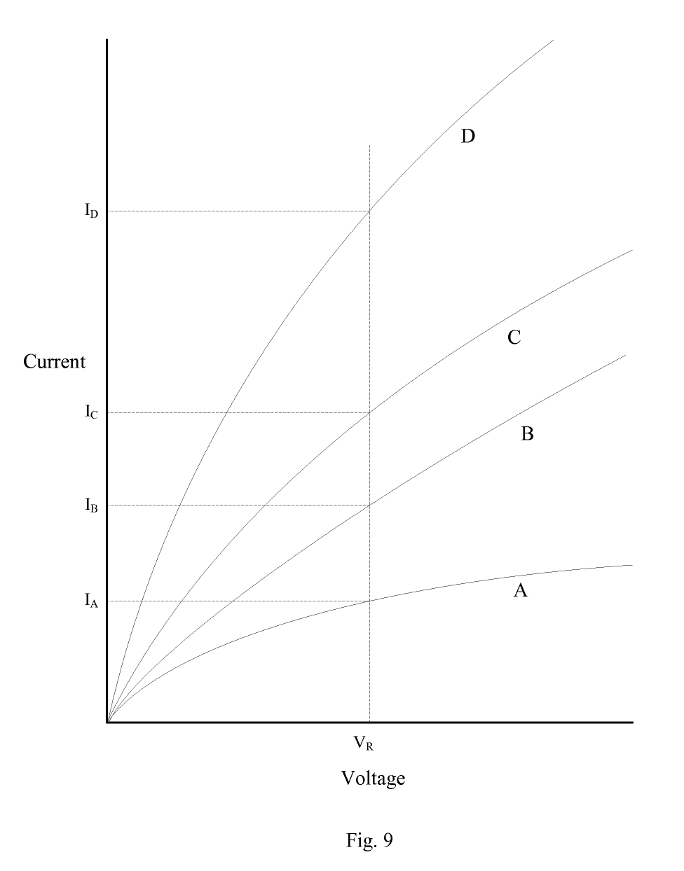

The memory cell of FIG. 2, then, can be in any one of four possible states. FIG. 9 shows exemplary I-V curves of each of these four states. Curve A is the I-V curve of the memory cell as formed, when all three antifuses are intact. Curve B is a memory cell with thick dielectric antifuse layer 122 broken down, while thinner dielectric antifuse layers 120 and 118 are intact. Curve C is a memory cell with thicker dielectric antifuse layers 122 and 120 broken down, and only thin dielectric antifuse layer 118 intact, while curve D is a memory cell with all three dielectric antifuse layers broken down. At a read voltage V_{R}, which is selected to be below the breakdown voltage of any of the dielectric antifuse layers, the current flowing between top conductor 400 and bottom conductor 200 for a cell on curve A, with all antifuses intact, is I_{A}. At the same read voltage V_{R}, the current for a cell on curve B, with the thick antifuse only broken down, is I_{B}. At V_{R}, the current for a cell on curve C, with two antifuses broken down and one intact antifuse remaining, is I_{C}. Finally, at V_{R}, the current for a cell on curve D, with all three antifuses broken down, is I_{D} These four different currents, I_{A}, I_{B}, I_{C}, and I_{D}, at the same applied read voltage V_{R} will correspond to four distinct data states which this memory cell can take.

It will be seen from FIG. 9 that sensed current changes with read voltage. Read voltage cannot be too high, however. A memory cell must be able to survive many reads during its lifetime without changing state. Each read requires application of a read voltage. In general, read voltages are selected to be small enough to prevent damage to the memory cell. For the memory cell of the present invention, with two or more antifuses, the state in which all antifuses have been broken down but one, when only the final very thin dielectric antifuse layer remains intact, may prove to be a relatively vulnerable state, which may suffer damage or inadvertent breakdown after many reads.

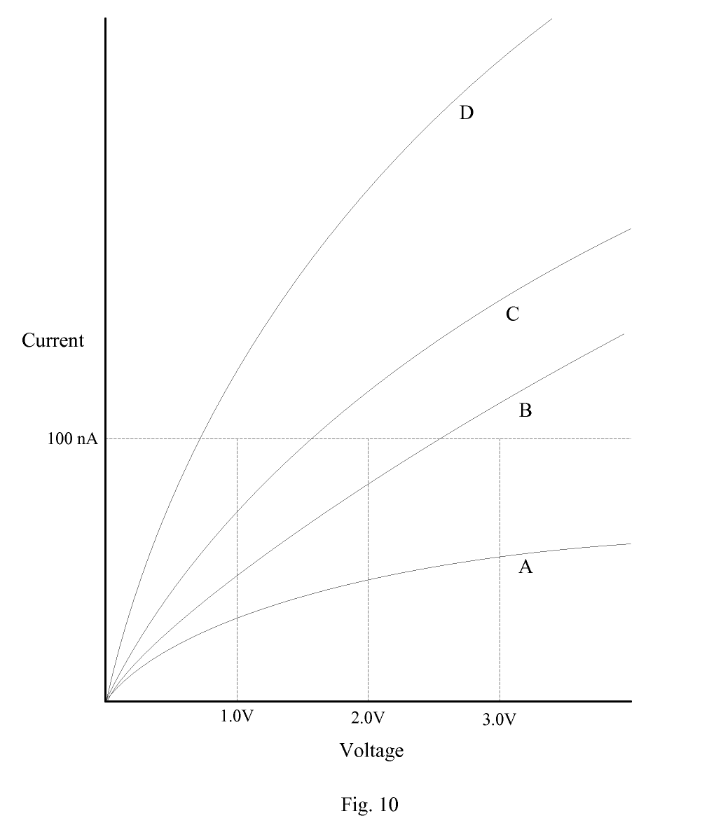

In some embodiments it may be desirable to perform a two-step read instead. FIG. 10 shows exemplary I-V curves for a memory cell with three antifuses. As in FIG. 9, curve A is a memory cell with all antifuses intact, curve B has one antifuse only broken down, curve C has two antifuses broken down, and curve D has all three antifuses broken down. An example of a two-step read, including example voltages and currents, will be provided. This example, and the values selected for voltage and current, are for clarity only, and are not intended to be limiting.

Sense amplifiers in the circuit are tuned to sense whether current is above or below 100 nanoamps, for example. In a first step, a first-read voltage of 2 volts is applied. If the current sensed is above 100 nanoamps, the memory cell is either on curve C or curve D; i.e. either one antifuse remains, or all three antifuses have been broken down. If the current sensed is below 100 nanoamps, the memory cell is either on curve A or curve B; i.e. either only one antifuse has been broken down, or all three antifuses are intact. The distinction between sensed current above 100 nanoamps or below 100 nanoamps therefore determines two possibilities for the states of the memory cell. C or D versus A or B. This distinction can be interpreted as one bit of binary information, which is referred to herein as the most significant bit (MSB).

If the current during the first-read was above 100 nanoamps, the read is performed at a lower voltage, for example 1 volt. With 1 volt applied between conductors, in this example, a memory cell on curve D, with all antifuses broken down, will have current above 100 nanoamps, while a memory cell on curve C, with one intact antifuse remaining, will have current below 100 nanoamps.

If the current during the first-read was below 100 nanoamps, the read is performed at a higher voltage, for example 3 volts. With 3 volts applied between conductors, in this example, a memory cell on curve B, with one antifuse broken down, will have current above 100 nanoamps, while a memory cell on curve A, with all antifuses intact, will have current below 100 nanoamps. Using this scheme, memory cells in the most vulnerable state, with only one antifuse remaining, are never exposed to the higher read voltage of 3 volts. It will be understood that the voltages and currents in this example are illustrative only, and different values may be selected.

Summarizing, then, if, in a given array, each memory cell can attain one of four states, each cell is read by (a) applying a read voltage between the first conductor and the second conductor of the memory cell, and (b) sensing a read current during application of the read voltage, wherein the read current corresponds to the data state of the memory cell. For the four different data states, the current is different so that each unique data state can be sensed. In one embodiment the read current during the first-read at a first read voltage is used to determine the MSB and the read current during the second read operation at the lower or higher read voltage is used to determine a second bit of information, which is referred to herein as the less significant bit (LSB).

A detailed example will be provided of fabrication of a first memory level in a monolithic three dimensional memory array, the first memory level formed according to an embodiment of the present invention. Detail from the earlier incorporated '283 and '986 applications, '067 and '837 publications, the '064 patent, and Herner, U.S. patent application Ser. No. 11/692,151, “Method to Form Upward Pointing P-I-N Diodes Having Large and Uniform Current,” filed Mar. 27, 2007, owned by the assignee of the present invention and hereby incorporated by reference, may be useful in fabricating such an array, but to avoid obscuring the invention, not all detail from these applications will be included. It will be understood that no teaching of these applications, publications, and patent is intended to be excluded. For clarity, many details are provided, including specific materials, thicknesses, conditions, and process steps. It will be understood by those skilled in the art that many of these details may be altered, omitted, or augmented while the results fall within the scope of the invention.

### Fabrication Example

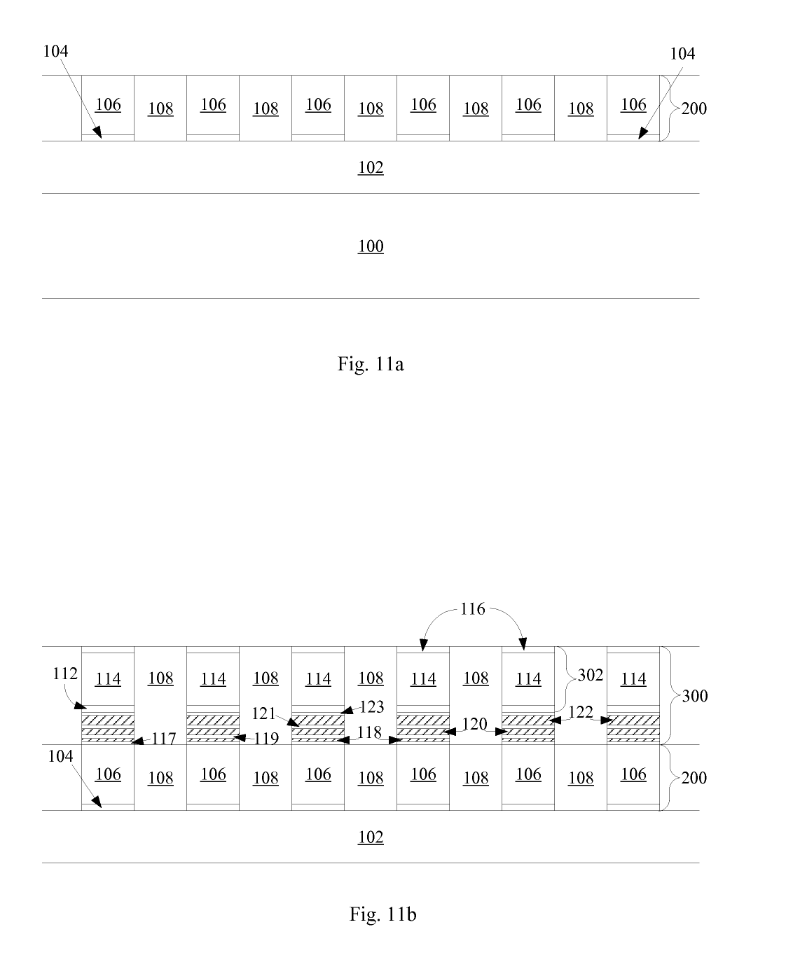

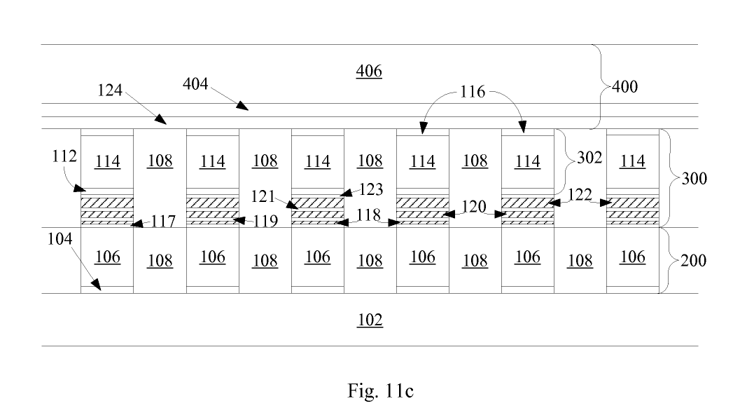

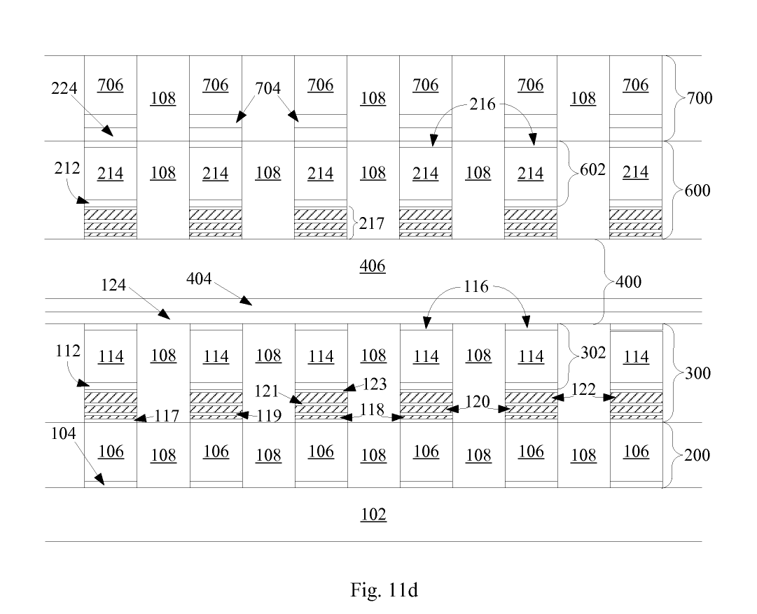

Turning to FIG. 11a, formation of the memory begins with a substrate 100. This substrate 100 can be any semiconducting substrate known in the art, such as monocrystalline silicon, IV-IV compounds like silicon-germanium or silicon-germanium-carbon, III-V compounds, II-VI compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, Si—C—O—H film, or any other suitable insulating material.

The first conductors 200 are formed over the substrate 100 and insulator 102. An adhesion layer 104 may be included between the insulating layer 102 and the conducting layer 106 to help conducting layer 106 adhere to insulating layer 102. If the overlying conducting layer 106 is tungsten, titanium nitride is preferred as adhesion layer 104. Conducting layer 106 can comprise any conducting material known in the art, such as tungsten, or other materials, including tantalum, titanium, cobalt, or alloys thereof.

Once all the layers that will form the conductor rails have been deposited, the layers will be patterned and etched using any suitable masking and etching process to form substantially parallel, substantially coplanar conductors 200, shown in FIG. 11a in cross-section. Conductors 200 extend out of the page. In one embodiment, photoresist is deposited, patterned by photolithography and the layers etched, and then the photoresist removed using standard process techniques. Conductors 200 may be formed at the desired pitch, for example 130 to 45 nm or less. In some embodiments, the width of conductors 200 and the gap between them may be about equal.

Next a dielectric material 108 is deposited over and between conductor rails 200. Dielectric material 108 can be any known electrically insulating material, such as silicon oxide, silicon nitride, or silicon oxynitride. In a preferred embodiment, silicon dioxide deposited by a high-density plasma method is used as dielectric material 108.

Finally, excess dielectric material 108 on top of conductor rails 200 is removed, exposing the tops of conductor rails 200 separated by dielectric material 108, and leaving a substantially planar surface. The resulting structure is shown in FIG. 11a. This removal of dielectric overfill to form the planar surface can be performed by any process known in the art, such as chemical mechanical planarization (CMP) or etchback. In an alternative embodiment, conductors 200 could be formed by a Damascene method instead.

Turning to FIG. 11b, next an optional conductive layer 117, for example about 50 angstroms of titanium nitride, tantalum nitride, or any appropriate conductor, will provide a uniform surface on which to deposit the thin dielectric antifuse layer to be formed, which may improve the uniformity of that layer. For example, a titanium nitride layer 117 may be deposited by a high-temperature CVD method, for example between about 450 and about 550 degrees C., for example about 500 degrees C.

A thin layer 118 of a dielectric material is formed on conductive layer 117. (For simplicity substrate 100 is omitted from FIG. 11b and succeeding figures; its presence will be assumed.) In some embodiments, the value of dielectric constant k for this material is preferably between 8 and 50, most preferably between about 8 and about 25. This layer is at least 5 angstroms thick, preferably between about 10 and about 40 angstroms thick, for example between about 10 and about 30 angstroms thick, for example about 20 angstroms. Preferred materials for thin dielectric antifuse layer 118 include HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, and ZrSiAlON. In some embodiments two or more of these materials may be blended. In one embodiment, dielectric layer 118 is HfO₂, and is formed by ALD, forming a very high-quality film. A high-quality film is preferably dense, as close to its theoretical density as possible; has complete coverage with few or no pinholes; and has a low density of electrical defects. In general it will be preferred for materials of comparable film quality having a higher dielectric constant to be thicker than those with a lower dielectric constant. Other, lower dielectric constant materials such as SiO₂, SiNₓ, or the like also may be used.

Conductive layer 119 is deposited on antifuse layer 118. It can be any appropriate conductive material, and is preferably the same material and thickness, and formed in the same manner, as conductive layer 117.

Middle dielectric antifuse layer 120 is deposited on conductive layer 119. In this example, middle antifuse layer 120 is of the same material as thin dielectric antifuse layer 118, and is formed in the same manner, such as by ALD. Middle antifuse layer 120 is thicker than thin antifuse layer 118, for example between about 20 and about 40 angstroms, for example about 30 angstroms.

Conductive layer 121 is deposited on antifuse layer 120. It can be any appropriate conductive material, and is preferably the same material and thickness, and formed in the same manner, as conductive layers 117 and 119.

Thick dielectric antifuse layer 122 is deposited on conductive layer 121. In this example, thick antifuse layer 122 is of the same material as thin dielectric antifuse layer 118 and middle dielectric antifuse layer 120, and is formed in the same manner, such as by ALD. Thick antifuse layer 122 is thicker than thin antifuse layer 120, for example less than about 80 angstroms. In one or more embodiments, the thick antifuse layer 122 may be between about 30 and about 80 angstroms, for example between about 40 and about 60 angstroms, for example about 40 angstroms. Thick dielectric antifuse layer 122 is typically at least 10 angstroms thicker than thin dielectric antifuse layer 118. In other embodiments, the deposition order of the dielectric antifuses may be reversed, with the thickest film being deposited first and the thinnest film being deposited last. In some embodiments, the deposition order for the dielectric antifuses, with respect to thickness, may be random.

Conductive layer 123 is deposited on thick antifuse layer 122. It can be any appropriate conductive material, and is preferably the same material and thickness, and formed in the same manner, as conductive layers 117, 119, and 121. In some embodiments this layer may be omitted.

Next semiconductor material that will be patterned into diodes is deposited. The semiconductor material can be silicon, germanium, a silicon-germanium alloy, or other suitable semiconductor or semiconductor alloy. For simplicity, this description will refer to the semiconductor material as silicon, but it will be understood that the skilled practitioner may select any of these other suitable materials instead.

Bottom heavily doped region 112 can be formed by any deposition and doping method known in the art. The silicon can be deposited and then doped, but is preferably doped in situ by flowing a donor gas providing p-type dopant atoms, for example boron, during deposition of the silicon. In preferred embodiments, the donor gas is BCl₃, and p-type region 112 is preferably doped to a concentration of about 1×10²¹ atoms/cm³. Heavily doped region 112 is preferably between about 100 and about 800 angstroms thick, most preferably about 200 angstroms thick.

Intrinsic or lightly doped region 114 can be formed next by any method known in the art. Region 114 is preferably silicon and has a thickness between about 1200 and about 4000 angstroms, preferably about 3000 angstroms. In general p-type dopants such as boron tend to promote crystallization; thus the silicon of heavily doped region 112 is like to be polycrystalline as deposited. Intrinsic region 114, however, is preferably amorphous as deposited.

Semiconductor regions 114 and 112 just deposited, along with conductive layer 123, thick dielectric antifuse layer 122, conductive layer 121, middle dielectric antifuse layer 120, conductive layer 119, thin dielectric antifuse layer 118, and conductive layer 117, will be patterned and etched to form pillars 300. Pillars 300 should have about the same pitch and about the same width as conductors 200 below, such that each pillar 300 is formed on top of a conductor 200. Some misalignment can be tolerated.

Pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask, or some other combination of materials may be used.

The photolithography techniques described in Chen, U.S. application Ser. No. 10/728436, “Photomask Features with Interior Nonprinting Window Using Alternating Phase Shifting,” filed Dec. 5, 2003; or Chen, U.S. application Ser. No. 10/815312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

Dielectric material 108 is deposited over and between the semiconductor pillars 300, filling the gaps between them. Dielectric material 108 can be any known electrically insulating material, such as silicon oxide, silicon nitride, or silicon oxynitride. In a preferred embodiment, silicon dioxide is used as the insulating material.

Next the dielectric material on top of pillars 300 is removed, exposing the tops of pillars 300 separated by dielectric material 108, and leaving a substantially planar surface. This removal of dielectric overfill can be performed by any process known in the art, such as CMP or etchback. After CMP or etchback, ion implantation is performed, forming heavily doped n-type top regions 116. The n-type dopant is preferably a shallow implant of arsenic, with an implant energy of, for example, 10 keV, and dose of about 3×10¹⁵/cm². This implant step completes formation of diodes 302. The resulting structure is shown in FIG. 11b. At this point the height of diodes 302 is between about 1500 and about 4000 angstroms, for example between about 2000 and about 2500 angstroms.

Turning to FIG. 11c, a layer 124 of a silicide-forming metal, for example titanium or cobalt, chromium, tantalum, platinum, nickel, niobium, or palladium, is deposited. Layer 124 is preferably titanium or cobalt; if layer 124 is titanium, its thickness may be between about 10 and about 100 angstroms, for example about 20 angstroms. Layer 124 is followed by titanium nitride layer 404. Both layers 124 and 404 may be between about 20 and about 100 angstroms, for example about 50 angstroms. Next a layer 406 of a conductive material, for example tungsten, is deposited. Layers 406, 404, and 124 are patterned and etched into rail-shaped top conductors 400, which preferably extend in a direction perpendicular to bottom conductors 200.

Next a dielectric material (not shown) is deposited over and between conductors 400. The dielectric material can be any known electrically insulating material, such as silicon oxide, silicon nitride, or silicon oxynitride. In a preferred embodiment, silicon oxide is used as this dielectric material.

Formation of a first memory level has been described. Additional memory levels can be formed above this first memory level to form a monolithic three dimensional memory array.

Referring to FIG. 11c, note that layer 124 of a silicide-forming metal is in contact with the silicon of top heavily doped region 116. During subsequent elevated temperature steps, the metal of layer 124 will react with some portion of the silicon of heavily doped n-type region 116 to form a silicide layer (not shown). This silicide layer forms at a temperature lower than the temperature required to crystallize silicon, and thus will form while regions 112, 114, and 116 are still largely amorphous. If a silicon-germanium alloy is used for top heavily doped region 116, a silicide-germanide layer may form, for example of cobalt silicide-germanide or titanium silicide-germanide. This silicide-germanide layer will similarly provide an advantageous crystallization template; as will a germanide layer forming on germanium.

In the example just described, the diodes 302 of FIG. 11c are upward-pointing, comprising a bottom heavily doped p-type region, a middle intrinsic region, and top heavily doped n-type region. In preferred embodiments, the next memory level to be monolithically formed above this one shares conductors 400 with the first memory level just formed; i.e., the top conductors 400 of the first memory level serve as the bottom conductors of the second memory level. If conductors are shared in this way, then the diodes in the second memory level are preferably downward-pointing, comprising a bottom heavily doped n-type region, a middle intrinsic region, and a top heavily doped p-type region.

To form the next memory level, a planarization step, for example by CMP, exposes the tops of conductors 400 at a substantially planar surface. Turning to FIG. 11d, a stack 217 is formed, which includes three dielectric antifuses and top, bottom, and intervening conductive layers, preferably of the same materials, the same thicknesses, and using the same methods, as layers 117-123 of pillars 300 in the first memory level.

Diodes are formed next. Bottom heavily doped region 212 can be formed by any deposition and doping method known in the art. The silicon can be deposited and then doped, but is preferably doped in situ by flowing a donor gas providing n-type dopant atoms, for example phosphorus, during deposition of the silicon. Heavily doped region 212 is preferably between about 100 and about 800 angstroms thick, most preferably about 100 to about 200 angstroms thick.

The next semiconductor region to be deposited is preferably undoped. In deposited silicon, though, n-type dopants such as phosphorus exhibit strong surfactant behavior, tending to migrate toward the surface as the silicon is deposited. Deposition of silicon will continue with no dopant gas provided, but phosphorus atoms migrating upward, seeking the surface, will unintentionally dope this region. As described in Herner, U.S. patent application Ser. No. 11/298,331, “Deposited Semiconductor Structure to Minimize N-Type Dopant Diffusion and Method of Making,” filed Dec. 9, 2005, hereby incorporated by reference, the surfactant behavior of phosphorus in deposited silicon is inhibited with the addition of germanium. Preferably a layer of a silicon-germanium alloy including at least 10 at % germanium is deposited at this point, for example about 200 angstroms of Si_{0.8}Ge_{0.2}, which is deposited undoped, with no dopant gas providing phosphorus. This thin layer is not shown in FIG. 11d.

Use of this thin silicon-germanium layer minimizes unwanted diffusion of n-type dopant into the intrinsic region to be formed, maximizing its thickness. A thicker intrinsic region minimizes leakage current across the diode when the diode is under reverse bias, reducing power loss. This method allows the thickness of the intrinsic region to be increased without increasing the overall height of the diode. As will be seen, the diodes will be patterned into pillars; increasing the height of the diode increases the aspect ratio of the etch step forming these pillars and the step to fill gaps between them. Both etch and fill are more difficult as aspect ratio increases.

Intrinsic region 214 can be formed next by any method known in the art. Region 214 is preferably silicon and preferably has a thickness between about 1100 and about 3300 angstroms, preferably about 1700 angstroms. The silicon of heavily doped region 212 and intrinsic region 214 is preferably amorphous as deposited.

Semiconductor regions 214 and 212 just deposited, along with underlying stack 217, will be patterned and etched to form pillars 600. Pillars 600 should have about the same pitch and about the same width as conductors 400 below, such that each pillar 600 is formed on top of a conductor 400. Some misalignment can be tolerated. Pillars 600 can be patterned and etched using the same techniques used to form pillars 300 of the first memory level.

Dielectric material 108 is deposited over and between the semiconductor pillars 600, filling the gaps between them. As in the first memory level, the dielectric material 108 on top of pillars 600 is removed, exposing the tops of pillars 600 separated by dielectric material 108, and leaving a substantially planar surface. After this planarization step, ion implantation is performed, forming heavily doped p-type top regions 216. The p-type dopant is preferably a shallow implant of boron, with an implant energy of, for example, 2 keV, and dose of about 3×10¹⁵/cm². This implant step completes formation of diodes 602. Some thickness of silicon is lost during the CMP step, so the completed diodes 602 have a height comparable to that of diodes 302.

Conductors 700 are formed in the same manner and of the same materials as conductors 400, which are shared between the first and second memory levels. A layer 224 of a silicide-forming metal is deposited, followed by a barrier layer such as titanium nitride layer 704 and layer 706 of a conductive material, for example tungsten. Layers 706, 704, and 224 are patterned and etched into rail-shaped conductors 700, which preferably extend in a direction substantially perpendicular to conductors 400 and substantially parallel to conductors 200. Dielectric material 108 is deposited over and between conductors 700. Additional memory levels can be monolithically formed above the first two memory levels.

Preferably after all of the memory levels have been formed, a single crystallizing anneal is performed to crystallize diodes 302, 602, and diodes on all other memory levels, for example at 750 degrees C. for about 60 seconds, though each memory level can be annealed as it is formed. The resulting diodes will generally be polycrystalline. Since the semiconductor material of these diodes is crystallized in contact with a silicide or silicide-germanide layer with which it has a good lattice match, the semiconductor material of the diodes will be low-defect and low-resistivity.

In this example, conductors are shared between memory levels; i.e. top conductor 400 serves as the bottom conductor of the next memory level above. In other embodiments, an interlevel dielectric (not shown) is formed above the first memory level of FIG. 11c, its surface planarized, and construction of a second memory level begins on this planarized interlevel dielectric, with no shared conductors.

In some embodiments, it may be preferred for the programming pulse to be applied with the diode in reverse bias. This may have advantages in reducing or eliminating leakage across the unselected cells in the array, as described in Kumar et al., U.S. patent application Ser. No. 11/496,986, “Method For Using A Memory Cell Comprising Switchable Semiconductor Memory Element With Trimmable Resistance,” filed Jul. 28, 2006, owned by the assignee of the present invention and hereby incorporated by reference.

An alternative method for forming a similar array in which conductors are formed using Damascene construction is described in Radigan et al., U.S. patent application Ser. No. 11/444,936, “Conductive Hard Mask to Protect Patterned Features During Trench Etch,” filed May 31, 2006, assigned to the assignee of the present invention and hereby incorporated by reference. The methods of Radigan et al. may be used to form an array according to aspects of the present invention.

The detailed example provided was for illustration only, and is just one of many possible alternatives. In the array just described, each memory cell included three antifuses; alternative embodiments may include two, four, or more antifuses. In the example described, the thinnest dielectric antifuse layer 118 was on the bottom, with thicker layer 120 above it and thickest layer 122 above it. The layers may appear in a different order.

To provide the largest possible separation between data states in a memory cell, it is preferable to have antifuses break down sequentially, and in order of increasing leakage current (i.e., with the least leaky antifuse breaking down first and the most leaky antifuse breaking down last). This is because the current-voltage (IV) characteristics of an unprogrammed memory cell that includes multiple antifuses are determined primarily by the IV characteristics of the “least leaky” antifuse. As such, breaking down the least leaky antifuse first will provide the largest change in the IV characteristics of a memory cell upon programming. For example, in a memory cell with two antifuse films, the breakdown voltage of the more leaky antifuse may be tuned so as to be at least, and preferably larger than, the breakdown voltage of the less leaky antifuse. This will insure that the more leaky antifuse will remain intact after the less leaky antifuse breaks down. In general, dielectric properties such as film composition, dielectric constant, thickness, and/or the like, may be selected so that antifuses of a memory cell break down in order of increasing leakage current. Even when two or more dielectric antifuses are broken down with a single programming pulse, the thickest dielectric antifuse will breakdown before the thinner dielectric antifuse of the same dielectric constant.

As noted earlier, the dielectric antifuse layers may be formed of different dielectric materials, for example having different values of dielectric constant k, instead of, or as well as, having different thicknesses. For example, a memory cell formed according to an embodiment of the present invention may have a first dielectric antifuse layer of silicon dioxide, which has a low dielectric constant, and a second dielectric antifuse layer of HfO₂, which has a higher dielectric constant, both in series with a diode. The thicknesses of these films can then be chosen such that the leakier film remains intact when the less-leaky film breaks down.

Many combinations of antifuses can be imagined for a memory cell; for example a cell may be formed including a first dielectric antifuse layer of silicon dioxide, a second of HfO₂ having a first thickness, and a third of HfO₂ having a second thickness less than the first. In other embodiments, silicon nitride or silicon oxynitride may serve as materials for dielectric antifuse layers as well.

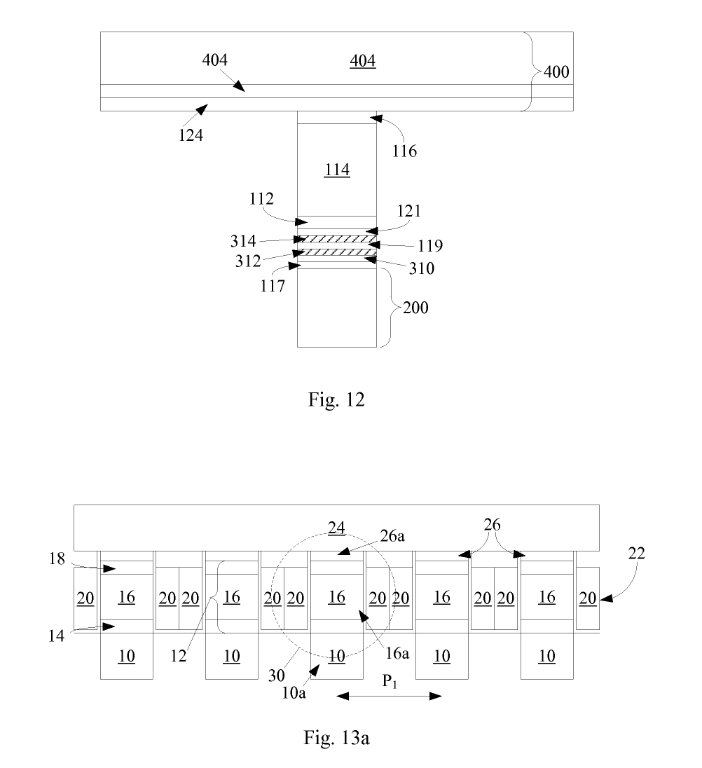

Turning to FIG. 12, in one alternative embodiment, after bottom conductors 200 are formed and first conductive layer 117 is deposited, a layer 310 of silicon is deposited. Layer 310 may be, for example, about 200 angstroms, and is preferably heavily doped n-type silicon, preferably doped in situ. Next a layer 312 of silicon dioxide is thermally grown on silicon layer 310, for example by a rapid thermal oxidation. In one embodiment, layer 312 is grown at 750 degrees C. by flowing 5 liters of O₂ and 5 liters of N₂ for 60 seconds. A layer is said to be grown rather than deposited when it is formed by consuming some portion of an underlying layer. This layer may be any appropriate thickness, for example about 16 angstroms. In an alternative embodiment, silicon layer 310 can be omitted, and silicon dioxide layer 312 can be deposited on conductive layer 117, for example by ALD. Fabrication continues with the deposition of conductive layer 119 and of dielectric antifuse layer 314, for example of HfO₂. Layer 314 may be, for example, between about 20 and about 30 angstroms. Any other appropriate material having a higher dielectric constant, for example Al₂O₃, ZrO₂, or a blend of HfO₂, Al₂O₃, and/or ZrO₂, or any of the earlier-named dielectrics, can be used. In this example, layer 314 is thicker than layer 312. But the silicon dioxide of layer 312 has a significantly lower dielectric constant k than does the HfO₂ of layer 314; thus, in some embodiments, dielectric antifuse layer 312 can be broken down first while dielectric antifuse layer 314 remains intact even if antifuse layer 312 is thinner than antifuse layer 314 by applying an appropriate programming pulse and limiting current, as described earlier. A conductive layer 121 is deposited, and diode 302 and top conductor 400 are fabricated as usual.

In some embodiments, one or more additional resistance-switching elements may be included in the memory cell in addition to the antifuses to achieve an additional memory state. Possible candidates include a switchable polysilicon resistor, a switchable polysilicon diode, a binary metal oxide layer, a carbon nano tube layer, etc.

In the embodiments so far described, a diode behaves as a steering element. A steering element is a device exhibiting non-ohmic behavior which allows for electrical isolation between memory cells on shared bitlines or wordlines. Another possible steering element is a transistor, for example a field effect transistor. A memory array of memory cells, each including a transistor and a resistance-switching element, is described in Petti et al., US Patent Publication No. 20060273298, “Rewriteable Memory Cell Comprising a Transistor and Resistance-Switching Material in Series,” filed Jun. 2, 2005, owned by the assignee of the present invention and hereby incorporated by reference.

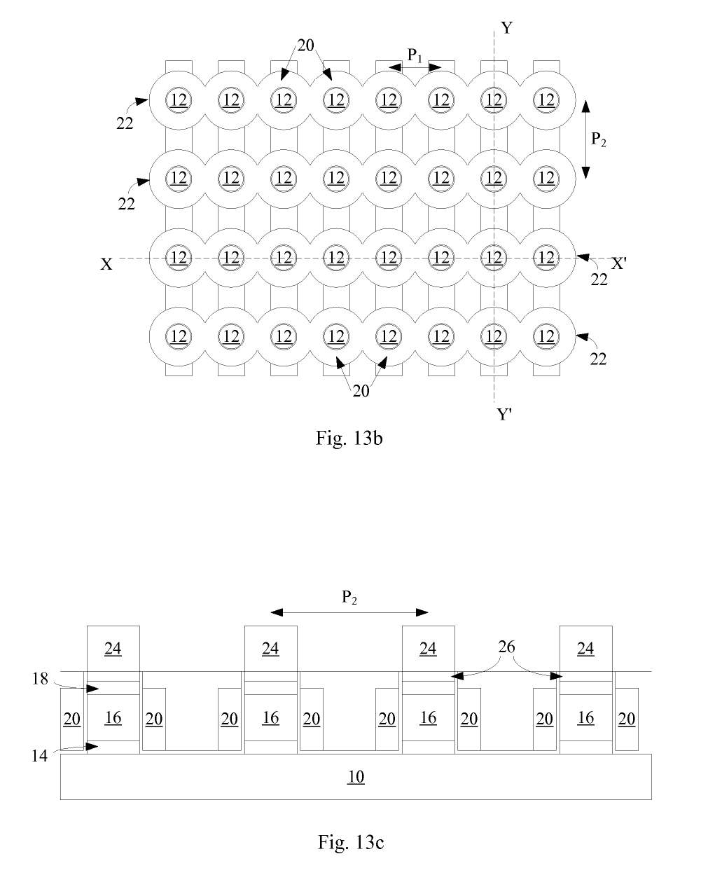

Petti et al. describe a memory cell having a layer of a resistivity-switching binary metal oxide or nitride formed in series with a MOS transistor. In embodiments of Petti et al., the MOS transistor is a thin-film transistor, having its channel layer formed in deposited polycrystalline semiconductor material rather than in a monocrystalline wafer substrate. Turning to FIG. 13a, in a preferred embodiment of Petti et al. a plurality of substantially parallel data lines 10 is formed. Semiconductor pillars 12 are formed, each above one of the data lines 10. Each pillar 12 includes heavily doped regions 14 and 18 which serve as drain and source regions, and a lightly doped region 16 which serves as a channel region. A gate electrode 20 surrounds each pillar 12.

FIG. 13b shows the cells of FIG. 13a viewed from above. In a repeating pattern, pitch is the distance between a feature and the next occurrence of the same feature. For example, the pitch of pillars 12 is the distance between the center of one pillar and the center of the adjacent pillar. In one direction pillars 12 have a first pitch P₁, while in other direction, pillars 12 have a larger pitch P₂; for example P₂ may be 1.5 times larger than P₁. (Feature size is the width of the smallest feature or gap formed by photolithography in a device. Stated another way, pitch P₁ may be double the feature size, while pitch P₂ is three times the feature size.) In the direction having the smaller pitch P₁, shown in FIG. 13a, the gate electrodes 20 of adjacent memory cells merge, forming a single select line 22. In the direction having larger pitch P₂, gate electrodes 20 of adjacent cells do not merge, and adjacent select lines 22 are isolated. FIG. 13a shows the structure in cross-section along line X-X′ of FIG. 13b, while FIG. 13c shows the structure in cross-section along line Y-Y′ of FIG. 13b.

Referring to FIG. 13a and 13c, reference lines 24, preferably perpendicular to data lines 10, are formed above the pillars 12, such that each pillar 12 is vertically disposed between one of the data lines 10 and one of the reference lines 24. A resistance-switching memory element 26 is formed in each memory cell between source region 18 and reference line 24, for example. Alternatively, resistance-switching memory element 26 can be formed between drain region 14 and data line 10. In preferred embodiments of the present invention, resistance-switching element 26 is replaced with two, three, or more dielectric antifuses separated by conductive layers.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method for programming a memory cell, the memory cell comprising a steering element; a first dielectric antifuse layer; and a second dielectric antifuse layer, the steering element, first dielectric antifuse layer, and second dielectric antifuse layer all arranged in series between a first conductor and a second conductor, wherein the method comprises:
applying a first programming pulse between the first conductor and the second conductor, wherein the first programming pulse results in dielectric breakdown of the first dielectric antifuse layer.

2. The method of claim 1 wherein applying the first programming pulse does not result in dielectric breakdown of the second dielectric antifuse layer.

3. The method of claim 1 further comprising applying a second programming pulse between the first and the second conductor to breakdown of the second dielectric antifuse layer.

4. The method of claim 1 wherein the steering element is a transistor.

5. The method of claim 1 wherein the steering element is a diode.

6. The method of claim 5 wherein the memory cell further comprises a conductive layer disposed between the first dielectric antifuse layer and the second dielectric antifuse layer.

7. The method of claim 6 wherein, during application of the first programming pulse, a current limit is applied to current through the memory cell.

8. The method of claim 6 further comprising:
applying a first read voltage between the first conductor and the second conductor; and
sensing a first read current during application of the first read voltage,
wherein the first read current corresponds to a first data bit of information stored in the memory cell.

9. The method of claim 8 further comprising:
applying a second read voltage between the first conductor and the second conductor; wherein the second read voltage is set to a higher or lower voltage value based on the first data bit of information; and
sensing a second read current during application of the second read voltage, wherein the second read current corresponds to a second data bit of information stored in the memory cell.

10. The method of claim 6 wherein the first dielectric antifuse layer is thicker than the second dielectric antifuse layer.

11. The method of claim 10 wherein the first dielectric antifuse layer and the second dielectric antifuse layer consist of the same dielectric material.

12. The method of claim 6 wherein the first dielectric antifuse layer comprises a first dielectric material and the second dielectric antifuse layer comprises a second dielectric material, wherein the first dielectric material has a dielectric constant substantially different than a dielectric constant of the second dielectric material.

13. The method of claim 12 wherein one of the first and second dielectric antifuse layers comprises silicon dioxide.

14. The method of claim 13 wherein the silicon dioxide is grown.

15. The method of claim 12 wherein one of the first and the second dielectric antifuse layers comprises HfO₂, Al₂O₃, ZrO₂, Ta₂O₅, or a blend thereof.

16. The method of claim 6 wherein the first dielectric antifuse layer or the second dielectric antifuse layer comprises SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

17. The method of claim 6 wherein the memory cell further comprises a third dielectric antifuse layer, the third dielectric antifuse layer arranged in series with the diode, the first dielectric antifuse layer, and the second dielectric antifuse layer between the first conductor and the second conductor.

18. The method of claim 17 wherein the second dielectric antifuse layer is disposed between the first dielectric antifuse layer and the third dielectric antifuse layer, and wherein the memory cell further comprises a conductive layer disposed between the second dielectric antifuse layer and the third dielectric antifuse layer.

19. The method of claim 17 wherein the first dielectric antifuse layer has a different thickness than the second dielectric antifuse layer.

20. The method of claim 19 wherein the first, second and third dielectric antifuse layers have different thicknesses.

21. The method of claim 17 wherein the first dielectric antifuse layer comprises a first dielectric material, and either the second or third dielectric antifuse layer comprises a second dielectric material.

22. The method of claim 21 wherein the first dielectric material has a higher dielectric constant than the second dielectric material.

23. The method of claim 6 wherein the first programming pulse has a voltage between about 4 and about 7 volts.

24. A method to program memory cells in a memory array, each memory cell comprising a diode, a first dielectric antifuse layer, and a second dielectric antifuse layer, wherein the diode, the first dielectric antifuse layer, and the second dielectric antifuse layer of each memory cell are arranged in series between a first conductor and a second conductor of the memory cell, the method comprising:
applying a first programming pulse between the first conductor and second conductor of a first plurality of the memory cells in a first memory cell state, wherein, after application of the first programming pulse, the first plurality of memory cells changes to a second memory cell state; and
applying a second programming pulse between the first conductor and second conductor of a second plurality of the memory cells, wherein, after application of the second programming pulse, the second plurality of memory cells changes to a third memory cell state.

25. The method of claim 24 wherein the second plurality of memory cells is contained in the first plurality of memory cells.

26. The method of claim 24 wherein the second plurality of memory cells contains at least some cells disjoint from the first plurality of memory cells.

27. The method of claim 24 further comprising:
applying a third programming pulse between the first conductor and second conductor of a third plurality of memory cells, wherein, after application of the third programming pulse, the third plurality of memory cells changes to a fourth memory cell state.

28. The method of claim 24 wherein the first dielectric antifuse layer of each memory cell is thicker than the second dielectric antifuse layer of each memory cell.

29. The method of claim 24 wherein the first dielectric antifuse layer of each memory cell comprises a first dielectric material and the second dielectric antifuse layer of each memory cell comprises a second dielectric material, wherein the first dielectric material has a substantially different dielectric constant than the second dielectric material.

30. The method of claim 24 wherein either the first dielectric antifuse layer or the second dielectric antifuse layer of each memory cell comprises SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

31. The method of claim 24 further comprising:
(i) performing a first reading of a plurality of the memory cells by:
(a) applying a first read voltage between the first conductor and the second conductor of the memory cells, and
(b) sensing a first read current during application of the first read voltage, wherein the first read current corresponds to a first bit of data stored in the memory cells;
(ii) performing a second reading of the plurality of memory cells by:
(a) applying a second read voltage between the first conductor and the second conductor of the memory cells, and
(b) sensing a second read current during application of the second read voltage, wherein the second read current corresponds to a second bit of data stored in the memory cells.

32. The method of claim 31 wherein the second read voltage is determined based on the first reading result for at least some of the memory cells.

33. The method of claim 31 wherein, during application of the second read voltage, none of the cells in the plurality of memory cells changes state.

34. The method of claim 32 wherein the second read voltage is less than the first read voltage when the first read current is less than a reference read current level used in the first reading of the plurality of the memory cells.

35. The method of claim 24 wherein each memory cell further comprises a third dielectric antifuse layer, and further comprising:
applying a third programming pulse between the first conductor and second conductor of a third plurality of memory cells, wherein, after application of the third programming pulse, the first dielectric antifuse layer, the second dielectric antifuse layer, and the third dielectric antifuse layer of the third plurality of memory cells are all broken down.

36. The method of claim 35 further comprising reading a read plurality of memory cells by:
(i) performing a first reading of the read plurality of memory cells by:
(a) applying a first read voltage between the first conductor and the second conductor of the read plurality of memory cells, and
(b) sensing a first read current during application of the first read voltage, wherein the first read current corresponds to a first bit of data stored in the read plurality of memory cells; and
(ii) performing a second reading of the read plurality of memory cells by:
(a) applying a second read voltage between the first conductor and the second conductor of the read plurality of memory cells, and
(b) sensing a second read current during application of the second read voltage, wherein the second read current corresponds to a second bit of data stored in the read plurality of memory cells.

37. The method of claim 36 wherein the second read voltage is determined based on the first reading result for at least some of the read memory cells.

38. The method of claim 24 wherein the diode of each memory cell comprises polycrystalline semiconductor material.

39. The method of claim 38 wherein the diode of each memory cell is a vertically oriented p-i-n diode.

40. The method of claim 38 wherein the memory cells are formed above a substrate, the substrate comprising monocrystalline silicon.

41. The method of claim 24 wherein the first dielectric antifuse layer is deposited by atomic layer deposition.

42. A method for programming memory cells in a memory array, wherein a first memory cell, a second memory cell, and a third memory cell each comprise a diode; a first dielectric antifuse layer; and a second dielectric antifuse layer, the diode, first dielectric antifuse layer, and second dielectric antifuse layer of each memory cell arranged in series between a first conductor and a second conductor of each memory cell, wherein the method comprises:
applying a first programming pulse between the first conductor and the second conductor of the second memory cell;
applying a second programming pulse between the first conductor and the second conductor of the third memory cell;
wherein, after application of the first and second programming pulses, the first memory cell is in a first data state, the second memory cell is in a second data state, and the third memory cell is in a third data state,
wherein the first data state is not the same as the second data state, and the third data state is not the same as the first data state or the second data state.

43. The method of claim 42 wherein no programming pulse is applied between the first conductor and the second conductor of the first memory cell.

44. The method of claim 42 wherein the diode of each memory cell is a p-i-n diode.

45. The method of claim 44 wherein the diode of each memory cell comprises polycrystalline or single crystal semiconductor material.

46. The method of claim 45 wherein the polycrystalline semiconductor material is silicon, germanium, or silicon-germanium.

47. The method of claim 42 wherein the first dielectric antifuse layer of each memory cell is thicker than the second dielectric antifuse layer of each memory cell.

48. The method of claim 47 wherein the first dielectric antifuse layer of each memory cell is at least ten angstroms thicker than the second dielectric antifuse layer of each memory cell.

49. The method of claim 48 wherein the first dielectric antifuse layer of each memory cell is between about 30 and about 80 angstroms thick.

50. The method of claim 49 wherein the second dielectric antifuse layer of each memory cell is between about 10 and about 40 angstroms thick.

51. The method of claim 42 wherein the first dielectric antifuse layer of each memory cell comprises a first dielectric material and the second dielectric antifuse layer of each memory cell comprises a second dielectric material, wherein the first dielectric material has a lower dielectric constant than the second dielectric material.

52. The method of claim 42 wherein the first dielectric antifuse layer or the second dielectric antifuse layer comprises SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

53. The method of claim 42 wherein a conductive layer is disposed between the first dielectric antifuse layer and the second dielectric antifuse layer.

54. A method to form a nonvolatile memory cell, the method comprising:
forming a rail-shaped bottom conductor above a substrate;
forming a rail-shaped top conductor above the bottom conductor;
forming a vertically oriented diode;
forming a first dielectric antifuse layer; and
forming a second dielectric antifuse layer,
wherein the diode, the first dielectric antifuse layer, and the second dielectric antifuse layer are electrically in series and disposed between the bottom conductor and the top conductor.

55. The method of claim 54 further comprising forming a first conductive layer disposed between the first dielectric antifuse layer and the second dielectric antifuse layer.

56. The method of claim 54 wherein the diode is a p-i-n diode.

57. The method of claim 56 wherein the diode is in a shape of a pillar.

58. The method of claim 54 wherein the step of forming the first dielectric antifuse layer comprises depositing the dielectric antifuse layer by atomic layer deposition.

59. The method of claim 54 wherein the first dielectric antifuse layer comprises SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

60. The method of claim 48 wherein the substrate comprises monocrystalline silicon.

61. A method for reading a memory cell of a nonvolatile memory array, the memory cell having at least two antifuse layers in series with a diode and a conductive layer between the antifuse layers, wherein the memory cell is in one of at least three resistance states, the method comprising:
impressing a read voltage across the memory cell so as to generate a read current through the memory cell, and
based on the read current, detecting in which of the at least three resistance states the memory cell resides.

62. The method of claim 61 wherein the at least three resistance states comprise:
a highest resistance state;
a first programmed resistance state having a lower resistance than the highest resistance state and produced by impressing a first programming pulse across the memory cell; and
a second programmed resistance state having a lower resistance than the first programmed state.

63. The method of claim 62 wherein the second programmed resistance state is produced by impressing a sequence of programming pulses across the memory cell that includes at least the first programming pulse and a second programming pulse.

64. The method of claim 62 wherein the second programmed resistance state is produced by impressing a second programming pulse across the memory cell in place of the first programming pulse, wherein the second programming pulse is different than the first programming pulse.

65. The method of claim 62 wherein the memory cell is in one of at least four resistance states.

66. The method of claim 65 wherein the fourth resistance state is produced by impressing a sequence of programming pulses across the memory cell that includes at least the first programming pulse, the second programming pulse and a third programming pulse.

67. The method of claim 65 wherein the fourth resistance state is produced by impressing a third programming pulse across the memory cell in place of the first and second programming pulses, wherein the third programming pulse is different than the first programming pulse and the second programming pulse.

68. The method of claim 61 further comprising:
impressing a pre-read voltage across the memory cell before impressing the read voltage across the memory cell;
detecting the pre-read current through the memory cell relative to a reference current; and
selecting a voltage value for the read voltage based on the detected pre-read current.

69. The method of claim 68 further comprising employing a read voltage that is greater than the pre-read voltage when no antifuse layers are broken down.

70. The method of claim 68 further comprising employing a read voltage that is less than the pre-read voltage when at least two antifuse layers are broken down.

71. A method to program memory cells in a memory array, each memory cell comprising a diode, a first dielectric antifuse layer, and a second dielectric antifuse layer, wherein the diode, the first dielectric antifuse layer, and the second dielectric antifuse layer of each memory cell are arranged in series between a first conductor and a second conductor of the memory cell, the method comprising:
determining a desired memory state for a first memory cell of the memory array; and
if the desired memory state for the first memory cell is a first memory state, applying a first programming pulse between the first conductor and second conductor of the first memory cell, wherein, after application of the first programming pulse, the first dielectric antifuse layer of the first memory cell is broken down, but the second dielectric antifuse layer of the first memory cell is not broken down.

72. The method of claim 71 further comprising, if the desired memory state for the first memory cell is a second memory state, applying a second programming pulse between the first conductor and second conductor of the first memory cell, wherein, after application of the second programming pulse, the first dielectric antifuse layer and the second dielectric antifuse layer of the first memory cell are both broken down.

73. The method of claim 71 wherein the first dielectric antifuse layer of each memory cell is thicker than the second dielectric antifuse layer of each memory cell.

74. The method of claim 71 wherein the first dielectric antifuse layer of each memory cell comprises a first dielectric material and the second dielectric antifuse layer of each memory cell comprises a second dielectric material, wherein the first dielectric material has a higher dielectric constant than the second dielectric material.

75. The method of claim 71 wherein either the first dielectric antifuse layer or the second dielectric antifuse layer of each memory cell comprises SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

76. The method of claim 35 further comprising:
applying a fourth programming pulse between the first conductor and second conductor of a fourth plurality of memory cells, wherein, after application of the fourth programming pulse, two of the antifuses are broken down while one of the antifuses remains intact.

77. The method of claim 24 wherein at least one of the antifuses is formed by depositing a material layer and growing the antifuse from the material layer.

78. A first memory level of an integrated circuit monolithically formed above a substrate, the first memory level comprising:
a plurality of substantially parallel, substantially coplanar bottom conductors;
a plurality of substantially parallel, substantially coplanar top conductors above the bottom conductors;
a plurality of vertically oriented diodes;
a plurality of first dielectric antifuse layers;
a plurality of second dielectric antifuse layers; and
a plurality of memory cells, wherein each memory cell comprises one of the diodes, one of the first dielectric antifuse layers, and one of the second dielectric antifuse layers disposed and arranged electrically in series between one of the bottom conductors and one of the top conductors.

79. The first memory level of claim 78 wherein the first dielectric antifuse layer of each memory cell is not in contact with the second dielectric antifuse layer.

80. The first memory level of claim 78 wherein a conductive layer is disposed between the first dielectric antifuse layer of each memory cell and the second dielectric antifuse layer of each memory cell.

81. The first memory level of claim 78 wherein the first dielectric antifuse layers are thicker than the second dielectric antifuse layers.

82. The first memory level of claim 81 wherein the thickness of the first dielectric antifuse layers is less than about 80 angstroms.

83. The first memory level of claim 82 wherein the thickness of the first dielectric antifuse layers is between about 30 and about 80 angstroms.

84. The first memory level of claim 82 wherein the thickness of the second dielectric antifuse layers is at least 5 angstroms.

85. The first memory level of claim 84 wherein the thickness of the second dielectric antifuse layers is between about 10 and about 40 angstroms.

86. The first memory level of claim 85 wherein the thickness of the first dielectric antifuse layers is between about 30 and about 50 angstroms, and wherein the thickness of the second dielectric antifuse layers is between about 10 and about 30 angstroms.

87. The first memory level of claim 78 wherein the first dielectric antifuse layers comprise a first dielectric material and the second dielectric antifuse layers comprise a second dielectric material, wherein the first dielectric material has a lower dielectric constant than the second dielectric material.

88. The first memory level of claim 87 wherein the first dielectric material is silicon dioxide.

89. The first memory level of claim 78 wherein the first dielectric antifuse layers or the second dielectric antifuse layers comprise SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

90. The first memory level of claim 78 wherein each of the diodes comprises polycrystalline semiconductor material.

91. The first memory level of claim 90 wherein the polycrystalline semiconductor material is in contact with titanium silicide, titanium silicide-germanide, cobalt silicide, or cobalt-silicide germanide.

92. The first memory level of claim 78 wherein both the first dielectric antifuse layer and the second dielectric antifuse layer of each memory cell are disposed between the diode and the top conductor or between the diode and the bottom conductor of that memory cell.

93. The first memory cell of claim 78 wherein the vertically oriented diode of each memory cell is a p-i-n diode.

94. The first memory cell of claim 78 wherein each memory cell further comprise a third dielectric antifuse layer disposed between one of the bottom conductors and one of the top conductors, wherein the third dielectric antifuse layer is not in contact with either the first dielectric antifuse layer or the second dielectric antifuse layer.

95. The first memory cell of claim 94 wherein a first conductive layer is disposed between the first dielectric antifuse layer and the third dielectric antifuse layer, and wherein a second conductive layer is disposed between the third dielectric antifuse layer and the second dielectric antifuse layer.

96. The first memory cell of claim 94 wherein a thickness of the third dielectric antifuse layer is less than a thickness of the first dielectric antifuse layer and greater than a thickness of second dielectric antifuse layer.

97. The first memory cell of claim 94 wherein the first dielectric antifuse layer comprises a first dielectric material, the second dielectric antifuse layer comprises a second dielectric material, and the third dielectric antifuse layer comprises a third dielectric material, wherein the first dielectric material has a lower dielectric constant than the third dielectric material, and the third dielectric material has a lower dielectric constant than the second dielectric material.

98. The first memory level of claim 78 wherein a second memory level is monolithically formed above the first memory level.

99. The first memory level of claim 78 wherein the substrate comprises monocrystalline silicon.

100. A monolithic three dimensional memory array comprising:
i) a first memory level monolithically formed above a substrate, the first memory level comprising:
a) a plurality of substantially parallel, substantially coplanar bottom conductors;
b) a plurality of substantially parallel, substantially coplanar top conductors above the bottom conductors;
c) a plurality of vertically oriented diodes;
d) a plurality of first dielectric antifuse layers;
e) a plurality of second dielectric antifuse layers; and
f) a plurality of memory cells, wherein each memory cell comprises one of the diodes, one of the first dielectric antifuse layers, and one of the second dielectric antifuse layers disposed between and arranged electrically in series between one of the bottom conductors and one of the top conductors, wherein the first dielectric antifuse layer of each memory cell is not in contact with the second dielectric antifuse layer; and
ii) a second memory level monolithically formed above the first memory level.

101. The monolithic three dimensional memory array of claim 100 wherein the substrate comprises monocrystalline silicon.

102. The monolithic three dimensional memory array of claim 100 wherein the vertically oriented diodes comprise polycrystalline semiconductor material.

103. The monolithic three dimensional memory array of claim 100 wherein the vertically oriented diodes are p-i-n diodes.

104. The monolithic three dimensional memory array of claim 100 wherein the first dielectric antifuse layers are thicker than the second dielectric antifuse layers.

105. The monolithic three dimensional memory array of claim 100 wherein the first dielectric antifuse layers comprise a first dielectric material and the second dielectric antifuse layers comprise a second dielectric material, wherein first dielectric material has a lower dielectric constant than the second dielectric material.

106. A nonvolatile memory cell comprising:
a bottom conductor;
a top conductor above the bottom conductor;
a vertically oriented diode;
a first dielectric antifuse layer; and
a second dielectric antifuse layer;
the diode, the first dielectric antifuse layer, and the second dielectric antifuse layer disposed and arranged electrically in series between the bottom conductor and the top conductor.

107. The memory cell of claim 106 wherein the first dielectric antifuse layer and the second dielectric antifuse layer are not in immediate contact.

108. The memory cell of claim 106 wherein a first conductive layer is disposed between the first dielectric antifuse layer and the second dielectric antifuse layer.

109. The memory cell of claim 106 wherein the diode is a p-i-n diode.

110. The memory cell of claim 106 wherein the first dielectric antifuse layer is thicker than the second dielectric antifuse layer.

111. The memory cell of claim 110 wherein the first dielectric antifuse layer and the second dielectric antifuse layer comprise the same dielectric material.

112. The memory cell of claim 111 wherein the dielectric material is SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.

113. The memory cell of claim 112 wherein the dielectric material is HfO₂.

114. The memory cell of claim 106 wherein the first dielectric antifuse layer comprises a first dielectric material and the second dielectric antifuse layer comprises a second dielectric material, wherein the first dielectric material has a lower dielectric constant than the second dielectric material.

115. The memory cell of claim 114 wherein the first dielectric material or the second dielectric material is SiO₂, SiNₓ, HfO₂, Al₂O₃, ZrO₂, TiO₂, La₂O₃, Ta₂O₅, RuO₂, ZrSiOₓ, AlSiOₓ, HfSiOₓ, HfAlOₓ, HfSiON, ZrSiAlOₓ, HfSiAlOₓ, HfSiAlON, ZrSiAlON, or a blend thereof.
